(19) United States
(12) Patent Application Publication
(10) Pub. No.: US 2026/0190950 A1
(43) Pub. Date: Jul. 2, 2026

(54) SUBSTRATE PROCESSING APPARATUS

(71) Applicant: SHIBAURA MECHATRONICS CORPORATION, Yokohama-shi, Kanagawa (JP)

(72) Inventors: Masaaki FURUYA, Yokohama-shi, Kanagawa (JP); Hiroaki KOBAYASHI, Yokohama-shi, Kanagawa (JP); Hideki MORI, Yokohama-shi, Kanagawa (JP)

(21) Appl. No.: 19/113,904

(22) PCT Filed: Sep. 19, 2023
(86) PCT No.: PCT/JP2023/033901

§ 371 Date: Mar. 2, 2026

(30) Foreign Application Priority Data
Sep. 21, 2022 (JP) 2022-150144

(51) Int. Cl. H10P 72/76; H10P 72/00

(52) U.S. Cl. CPC H10P 72/7624; H10P 72/0422; H10P 72/7606; H10P 72/7612

(57) ABSTRACT

According to one embodiment, a substrate processing apparatus in which a plurality of clamp pins synchronizes to stably position a substrate at the center of rotation is provided. A substrate processing apparatus 1 of the embodiment includes: a clamp lever 12 moving at least three clamp pins 11 between an open position that is apart from the outer edge We of the substrate W and a close position where the clamp pins 11 contact the outer edge We of the substrate W and hold the substrate W according to rotation around an axis in the horizontal direction; a lifting ring 15 rotating the clamp lever 12 according to lifting and lowering; a rotator 30 rotating the substrate W held by the clamp pins 11; a rotation mechanism 40 rotating the rotator 30 around an axis Ax; a lifting mechanism 50 lifting and lowering the lifting ring 15; a biasing member 56 biasing the clamp lever 12 in a direction the clamp pins 11 moves to the close position; a synchronization ring 61 that is rotatable around the axis Ax and that cannot be lifted and lowered; a conversion mechanism 62 converting lifting and lowering of the lifting ring 15 to rotation of the synchronization ring 61 while maintaining posture of the lifting ring 15; and a supplier 70 supplying processing liquid on the substrate W rotated by the rotator 30.

### FIELD OF INVENTION

The present disclosure relates to a substrate processing apparatus.

### BACKGROUND

In the manufacturing process such as for semiconductor devices and flat panel displays, etching liquid is supplied on film provided on a surface of substrates such as wafers and glass substrates, to form desired patterns. As an apparatus to perform such a etching process, a substrate processing apparatus to supply etching liquid on a center region of the rotating substrate is suggested. In this case, since the etching liquid supplied on the center region of the substrate spreads toward the periphery of the substrate due to centrifugal force, the surface of the substrate is etched by the supplied etching liquid.

In such substrate processing, contact traces and others left on the surface of the substrate where the substrate was supported will lead to a reduction in the quality of the substrate. Furthermore, the contact traces left on the back surface of the substrate other than the surface of the substrate are also not preferable as they affect the quality of the substrate. Therefore, a plurality of holding members hold an outer edge of the substrate, rather than the surface or the back surface, while the processing of the rotating substrate. For example, a plurality of clamp pins that moves in the direction contacting or getting apart from the outer edge of the substrate is used for such holding members (refer Patent Document 1).

### PRIOR ART DOCUMENT

### Patent Document

Patent Document 1: JP H10-209254A

### SUMMARY OF INVENTION

### Problems to be Solved by Invention

The plurality of the clamp pins needs to move between an open position that is apart from the substrate and a close position where the clamp pins contact and hold the outer edge of the substrate. However, if each clamp pin is driven independently, the center of the substrate and the center of rotation may vary. Furthermore, even if the independently-driven clamp pins could hold the substrate with the center of the substrate and the center of rotation aligned, force is applied on the clamp pins from the substrate due to centrifugal force such that the clamp pins open, causing the center of the substrate to displace from the rotation axis.

The problem to be solved by the invention is to provide a substrate processing apparatus in which a plurality of clamp pins synchronizes to stably position the substrate at the center of rotation.

### Means to Solve the Problem

A substrate processing apparatus of the present disclosure includes:
at least three clamp pins holding an outer edge of a substrate;
a clamp lever to which the clamp pins are provided and which moves the clamp pins between an open position that is apart from the outer edge of the substrate and a close position where the clamp pins contact the outer edge of the substrate and hold the substrate according to rotation around a horizontal rotation axis;
a lifting ring rotating the clamp lever according to lifting and lowering;
a rotator to which the horizontal rotation axis of the clamp lever is provided and which rotates the substrate held by the clamp pins, together with the clamp lever, and the lifting ring;
a rotation mechanism rotating the rotator around a vertical rotation axis;
a lifting mechanism lifting and lowering the lifting ring along the vertical rotation axis;
a biasing member biasing the clamp lever in a direction the clamp pins move to the close position;
a synchronization ring that is rotatable around the vertical rotation axis and that cannot be lifted and lowered;
a conversion mechanism converting lifting and lowering of the lifting ring by the lifting mechanism to rotation of the synchronization ring while maintaining posture of the lifting ring in the horizontal direction; and
a supplier and supplying processing liquid on the substrate held by the clamp pin and rotated by the rotator.

### Effect of Invention

According to the present invention, a substrate processing apparatus in which a plurality of clamp pins synchronizes to stably position the substrate at the center of rotation can be provided.

### BRIEF DESCRIPTION OF DRAWINGS

FIG. 1 a figure illustrating the configuration of the substrate processing apparatus according to the embodiment.

FIG. 2 is a perspective view illustrating the internal structure of the substrate processing apparatus.

FIG. 3 is a perspective view illustrating the configuration of the substrate holding portion of FIG. 2.

FIG. 4 is a vertical cross-sectional view illustrating the substrate holding state (A) and the release state (B) of FIG. 2 along the central axis.

FIG. 5 a simplified vertical cross-sectional view in two directions illustrating the case when the clamp pin is in the close position.

FIG. 6 is a simplified vertical cross-sectional view illustrating the normal (A) and abnormal (B) holding by the clamp pin.

FIG. 7 is a simplified vertical cross-sectional view illustrating the case in which one clamp pin is in the close position and the other clamp pin is in the open position.

FIG. 8 is an explanatory view illustrating the principle of tilting of the lifting ring when the holding by the clamp pin is abnormal.

FIG. 9 is a flowchart illustrating the procedures of the substrate processing.

FIG. 10 is a simplified vertical cross-sectional view illustrating the aspect in which the holding by the clamp pin is abnormal in a substrate processing apparatus without the synchronization ring.

FIG. 11 is an explanatory view illustrating the example of the conversion mechanism.

FIG. 12 is a perspective view illustrating the modified example of the conversion mechanism using a sliding shaft.

FIG. 13 is a perspective view illustrating the modified example of the conversion mechanism using a cam.

FIG. 14 is a perspective view illustrating the modified example with a single synchronization ring.

### EMBODIMENTS

Hereinafter, embodiments of the present disclosure will be described referring to the figures.

### SUMMARY

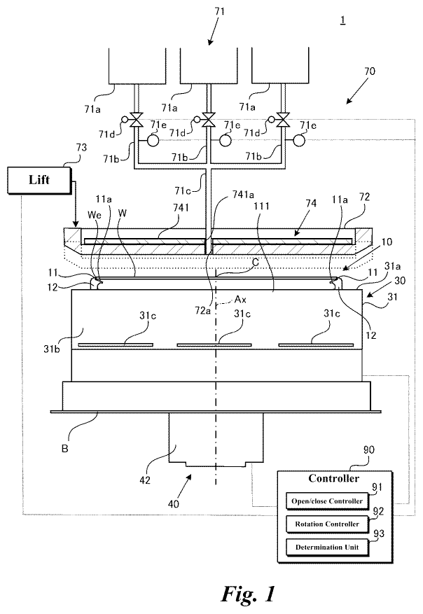

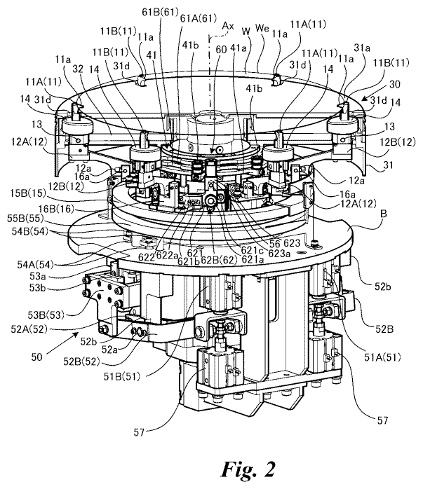

As illustrated in FIG. 1, a substrate processing apparatus 1 of the present embodiment is an apparatus to process a substrate W while holding and rotating the substrate W. For example, the substrate W that is a processing target is wafers and glass substrates used in the manufacturing process of microstructures such as semiconductor devices and flat panel displays. For example, the processing by the substrate processing apparatus 1 is wet processing in which the substrate W is processed by supplying processing liquid while rotating the substrate W. A surface of the substrate W that is the processing target is the front surface, and an opposite surface is the back surface. The wet processing of the present embodiment includes an etching process to etch film provided on the front surface of the substrate W, and a washing process to wash the substrate W by washing liquid.

As illustrated in FIGS. 1 and 2, the substrate processing apparatus 1 includes a holder 10, a rotator 30, a rotation mechanism 40, a lifting mechanism 50, a synchronization mechanism 60, a supplier 70, a detector 80 (refer FIG. 5), and a controller 90.

### (Holder)

As illustrated in FIG. 1, the holder 10 holds the substrate W in the horizontal direction. As illustrated in FIGS. 2 to 4, the holder 10 includes clamp pins 11, a clamp lever 12, a rotation shaft 13, a cover 14, a lifting ring 15, and a clamp base 16.

The clamp pins 11 are a plurality of members to hold an outer edge We of the substrate W. The clamp pin 11 has a truncated-cone shape with a reduced diameter at the lower side. The clamp pins 11 may be a portion with a face that can contact the outer edge We of the substrate W and hold the substrate W. Therefore, the shape of the clamp pin 11 may be cylinders, prisms, and cones, but is not limited thereto. It is preferable that, when the clamp pin 11 contact the outer edge We, the clamp pin 11 is at a height that does not contact and affect the front surface and the back surface of the substrate W and that can suppress the effect to the flow of the processing liquid.

Furthermore, a support 11a is provided in a lower portion of the clamp pin 11. The support 11a has a wedge-shape and is formed so that a pointed end thereof is directed toward an axis Ax of the rotating rotator 30 described later. A top surface of the support 11a is inclined to lower toward the axis Ax.

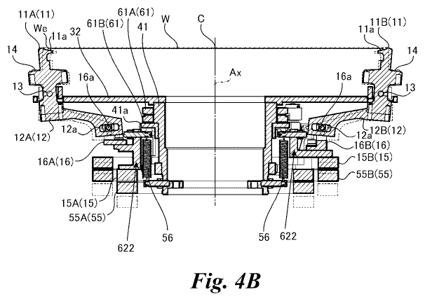

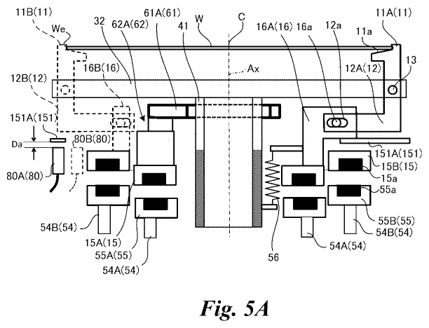

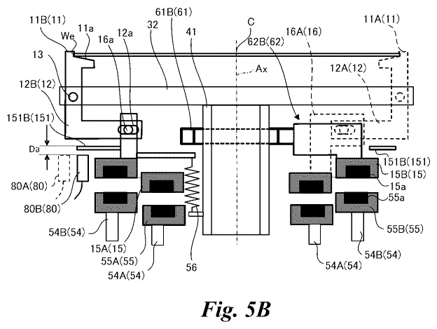

The clamp pin 11 is provided at one end of the clamp lever 12, and the clamp lever 12 moves the clamp pin 11 between an open position where the clamp pin 11 contacts the outer edge We of the substrate W and holds the substrate W (refer FIG. 4a) and a close position where the clamp pin 11 is apart from the outer edge We of the substrate W (refer FIG. 4b), according to rotation around the horizontal axis. The clamp lever 12 is an L-shaped member.

The rotation shaft 13 is a shaft to rotate the clamp lever 12. The rotation shaft 13 is provided on the rotator 30 described later in the tangential direction (horizontal direction) of the circle of rotation of the rotator 30. The clamp lever 12 rotated with the rotation shaft 13 as the fulcrum. By this, the clamp pin 11 moves between the open position and the close position.

A connection hole 12a for connection with the clamp base 16 described later is formed at the other end of the clamp lever 12. The connection hole 12a is a long hole along the radial direction of the rotator 30. The cover 14 is a cylindrical member provided so that one end of the clamp lever 12 protrudes upward so as to expose the clamp pin 11. The cover 14 has an inclined surface 14a on the upper surface thereof provided at the rotation-mechanism-40 side than the rotation shaft 13 of the clamp lever 12.

The plurality of the clamp pin 11 and the clamp lever 12 are arranged at equal intervals along the perimeter of the substrate W. Six clamp pins 11 are provided, in which three clamp pins 11 arranged one each around the axis Ax form a set. By this, six clamp pins 11 are arranged at intervals of 60 degrees. One set of three clamp pins 11 are called a clamp pin 11A, and the other three clamp pins 11 are called a clamp pin 11B. Note that the number of the clamp pins 11 is not limited, and more than six clamp pins 11 may be provided with more than three clamp pins 11 forming a set.

Furthermore, the clamp lever 12 to which the clamp pin 11A is provided is called a clamp lever 12A, and the clamp lever 12 to which the clamp pin 11B is provided is called a clamp lever 12B. In the following description, the clamp pins 11A and 11B are described as the clamp pin 11 and the clamp levers 12A and 12B are described as the clamp lever 12, unless otherwise distinguished.

The lifting ring 15 rotates the clamp lever 12 according to lifting and lowering. The lifting ring 15 is an annular member with the axis Ax as the center, and is arranged around the rotation shaft 41 described later. Each clamp lever 12 is arranged in the lifting ring 15 of the present embodiment. Furthermore, a magnet 15a is provided to the lifting ring 15 (refer FIGS. 5 to 7). The lifting ring 15 includes a pair of lifting rings 15A and 15B. The lifting rings 15A and 15B have a concentric annular shape, the lifting ring 15A with diameter smaller than the lifting ring 15B is arranged inside the lifting ring 15B. The inner lifting ring 15A corresponds to the clamp lever 12A and the clamp pin 11A, and the outer lifting ring 15B corresponds to the clamp lever 12B and the clamp pin 11B. Hereinafter, the lifting rings 15A and 15B are described as the lifting ring 15 unless otherwise distinguished.

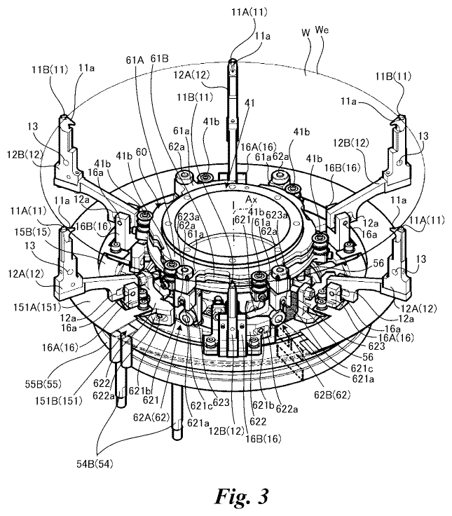

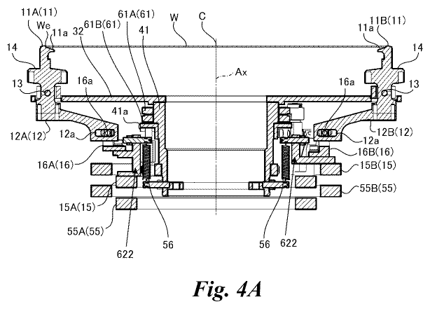

As illustrated in FIGS. 3 and 5 to 7, a height detection plate 151 for detecting a height position is provided in the lifting ring 15. The height detection plate 151 is a ring-shaped plate arranged coaxially with the lifting ring 15 to surround the outer circumference of the lifting ring 15. The height detection plate 151 is fixed to the lifting ring 15 via a plurality of connectors extending from the inner circumference thereof. Since the relative position between the height position of the height detection plate 151 and the height position of the lifting ring 15 is constant, the height position of the height detection plate 151 reflects the height position of the lifting ring 15.

The present embodiment includes two height detection plates 151A and 151B. The height detection plate 151A is provided in the lifting ring 15A. The height detection plate 151B is provided in the lifting ring 15B. The height detection plate 15A indicates the height position of the lifting ring 15A, and the height detection plate 151B indicates the height position of the lifting ring 15B. Hereinafter, the height detection plates 151A and 15B are described as the height detection plate 151 unless otherwise distinguished.

The clamp base 16 supports each clamp lever 12 rotatably relative to the lifting ring 15. In detail, the clamp base 16 is supported by the lifting ring 15 via a lifting guide 622 described later. That is, the clamp base 16 is installed above the lifting guide 622. A lifting shaft 16a inserted to the connection hole 12a of the clamp lever 12 is provided in the clamp base 16 in the horizontal direction. The lifting shaft 16a moves along the connection hole 12a according to lifting and lowering of the lifting ring 15, while biasing the connection hole 12a in the vertical direction to rotate the clamp lever 12, so that the clamp pin 11 moves between the open position and the close position.

As illustrated in FIGS. 5 to 7, three clamp bases 16A are provided to the inner lifting ring 15A and are each connected to the clamp lever 12A. Therefore, three clamp levers 12A synchronously rotate due to the lifting and lowering of the lifting ring 15A, so that three clamp pins 11A contact or get apart from the substrate W. Three clamp bases 16B are provided to the outer lifting ring 15B and are each connected to the clamp lever 12B. Therefore, three clamp levers 12B synchronously rotates due to the lifting and lowering of the lifting ring 15B, so that three clamp pins 11B contact or get apart from the substrate W. Hereinafter, the clamp bases 16A and 16B are described as the clamp base 16 unless otherwise distinguished.

### (Rotator)

The rotation shaft 13 of the clamp lever 12 is provided to the rotator 30, and the rotator 30 rotates the substrate W held by the clamp pin 11 together with the clamp lever 12 and the lifting ring 15. As illustrated in FIGS. 1 and 2, the rotator 30 includes a rotation cover 31 and a rotation base 32. The rotation cover 31 has a cylindrical shape with one end blocked by a table 31a. The table 31a is a circular face with a diameter larger than the substrate W. A drainage 31c that is a through hole to drain the processing liquid is formed in a side surface 31b of the rotation cover 31. Note that FIG. 4 is a cross-sectional view of the inside of the rotation cover 31 cut along the vertical plane including the axis Ax.

The rotation base 32 is a disc-shaped member coaxial with the table 31a provided on a lower surface of the table 31a. This axis is the axis Ax that is the center of rotation. The rotation shaft 13 of the clamp lever 12 is provided in the rotation base 32. The rotator 30 is provided on a base portion B fixed on a trestle installed on an unillustrated installation surface and is rotatable by the rotation mechanism 40 described later.

The lifting ring 15, the clamp base 16, and the other end of the clamp lever 12 (connecting with the clamp base 16) are arranged under the table 31a. Also, the table 31a is provided with a plurality of through holes 31d at positions along the perimeter of the substrate W. In the present embodiment, six through holes 31d are provided at intervals of 60 degrees. One end of the clamp lever 12 protrudes upward from the through hole 31d, and the clamp pin 11 is exposed from the through hole 31d.

Here, the clamp pin 11 protrudes from an upper surface of the table 31a via the through hole 31d, and the cover 14 of the clamp pin 11 is held so as to be positioned on the lower surface of the table 31a. Furthermore, to prevent the processing liquid from entering inside the rotation mechanism 40 from the through hole 31d, a gap between the lower surface of the table 31a and the upper surface of the cover 14 of the clamp pin 11 is very small, and when the entire upper surface of the cover 14 is horizontal, the upper surface of the cover 14 may contact the lower surface of the table 31a by the rotation of the clamp lever 12, interfering the opening and closing action.

As described above, the cover 14 has the inclined surface 14a on the upper surface thereof provided at the rotation-mechanism-40 side than the rotation shaft 13 of the clamp lever 12. By this, the gap between the lower surface of the table 31a and the cover 14 can be reduced, while still preventing the cover 14 from contacting the lower surface (virtual line a) of the table 31a interfering the opening and closing action, even if the clamp lever 12 rotates and the clamp pin 11 moves between the open position and the close position.

The through hole 31d has a size that allows the opening and closing action of the clamp lever 12. Six clamp pins 11 exposed from the table 31a moves to the close position and contacts the outer edge We of the substrate W to hold the substrate W with a gap between the table 31a.

### (Rotation Mechanism)

As illustrated in FIGS. 1 and 4, the rotation mechanism 40 rotates the rotator 30 around the axis Ax. The rotator 30 of the present embodiment is connected to the rotation shaft 41. The rotation shaft 41 is a cylinder fixed coaxially to the rotation base 32 at an upper end thereof. Note that the rotation shaft includes a case in which a plurality of cylinders is connected in the axial direction, and in the present embodiment, the entire shaft is called the rotation shaft 41. The axis Ax is a virtual axis that is the center of rotation of the rotator 30. The axis Ax of the present embodiment is the center of rotation of the rotation shaft 41 in the vertical direction. When the substrate W is held normally, a center C of the substrate W held at the outer edge We by the clamp pin 11 is positioned on this axis Ax. Note that, the rotation shaft 41 may be at a position offset from the axis Ax, and the rotation mechanism 40 may be a mechanism that transmits the rotation from the rotation shaft 41 by gears, etc. That is, the rotation shaft 41 connected to the rotator 30 may be directly or indirectly connected to the rotator 30 if the rotation shaft 41 can rotate the rotator 30.

Furthermore, as illustrated in FIG. 1, the rotation mechanism 40 includes a drive source 42. The drive source 42 is a hollow motor with a hollow rotor and a stator to rotate the rotor, and is fixed to a base portion B (refer FIG. 2). A lower end of the rotation shaft 41 is connected to the rotor of the drive source 42. The drive source 42 conducts electricity to a coil of the stator to rotate the rotation shaft 41 together with the rotor.

### (Lifting Mechanism)

The lifting mechanism 50 lifts and lowers the lifting ring 15 without contact by repulsive force of magnets. As illustrated in FIG. 2, the lifting mechanism 50 includes an open/close cylinder 51, an open/close lever 52, an open/close lifter 53, an open/close rod 54, an open/close ring 55, a biasing member 56, and a stopper cylinder 57. The open/close cylinder 51 is fixed to the lower portion of the base portion B so that a drive rod extends downward in the vertical direction. The open/close cylinder has two open/close cylinders 51A and 51B to independently lift and lower the lifting rings 15A and 15B.

The open/close lever 52 is a member provided in the base portion B and rotatable around a fulcrum 52a as a center. The fulcrum 52a is installed in a support member 52b extending below the base portion B in the vertical direction. An end of the open/close lever 52 is rotatably connected to the drive rod of the open/close cylinder 51. The open/close lever 52 has a C-shape surrounding the drive source 42. The open/close lever 52 includes two open/close levers 52A and 52B corresponding to two open/close cylinders 51A and 51B However, since the open/close lever 52A is nested inside the open/close lever 52B, the open/close lever 52A cannot be seen in FIG. 2.

The open/close lifter 53 is provided in the base portion B and can be lifted and lowered. In detail, the open/close lifter 53 is supported by the support member 53a extending below the base portion B in the vertical direction via a linear guide 53b, and can be lifted and lowered. The open/close lifters 53 are configured in a pair with the drive source 42 therebetween, and are rotatably connected to both ends of the open/close lever 52 in a C-shape. The pair of open/close lifters 53 connected to the open/close lever 52B is a open/close lifter 53B. The pair of open/close lifters connected to the open/close lever 52A is an open/close lifter 53A described later which is inside of the open/close lifter 53B, and cannot be seen in FIG. 2.

The open/close rod 54 is a cylindrical member, is provided to be lifted and lowered by the open/close lifter 53, and protrudes above the base portion B. Two open/close rods 54 are provided each to one open/close lifter 53. A pair of the open/close rods 54 provided to the open/close lifter 53A is the open/close rod 54A, and pair of the open/close rods 54 provided to the open/close lifter 53B is the open/close rod 54B.

The open/close ring 55 is a ring-shaped member to which a magnet 55a is provided (refer FIGS. 5 to 7). This magnet is arranged to generate repulsive force against the magnet 15a of the lifting ring 15. The open/close ring 55 is arranged in a position below and facing the lifting ring 15, and biases the lifting ring 15 upward without contact by utilizing the repulsive force of the magnets 15a and 55a. The open/close ring 55 has a pair of open/close rings 55A and 55B, which face the lifting rings 15A and 15B respectively.

The open/close ring 55 is supported at an upper end of the open/close rod 54, and is lifted or lowered together with the open/close lifter 53 by the open/close lever 52 rotated by the open/close cylinder 51. Each of a pair of the open/close rings 55A and 55B is driven independently. When the open/close cylinder 51A is lifted or lowered, the open/close lever 52A rotates, and since the open/close lifter 53A is lifted or lowered, the open/close rod 54A lifts or lowers the open/close ring 55A. When the open/close cylinder 51B is lifted or lowered, the open/close lever 52B rotates, and since the open/close lifter 53B is lifted or lowered, the open/close rod 54B lifts or lowers the open/close ring 55B.

The biasing member 56 is a member to bias the clamp lever 12 in the direction the clamp pin 11 is in the close position. The biasing member 56 is provided between the rotation shaft 41 and each clamp base 16 (refer FIG. 4) and biases the lower end of the clamp lever 12 downward. For example, the biasing member 56 is a tensile coil spring in which both ends are hooked between a pin protruding from the rotation shaft 41 in the horizontal direction and a pin penetrating the lifting guide 622 described later. The biasing member 56 biases each clamp pin 11 to be in the close position by biasing the lower end of each clamp lever 12 downward.

In the present embodiment, a number of the biasing member 56 is six that is the same as the number of the clamp levers 12. Three biasing members 56 corresponds to three clamp levers 12A, and three biasing members 56 corresponds to three clamp levers 12B. Since six biasing members 56 are arranged at equal intervals on the circumference, the force by the biasing member 56 applied from the clamp pin 11 to the outer edge We of the substrate W acts evenly and is balanced, so that the center C of the substrate W held by the clamp pin 11 is positioned to match with the axis Ax. When two open/close rings 55A and 55B are lifted by the open/close cylinders 51A and 51B, six clamp levers 12A and 12B resist against the biasing force of the biasing members 56 and rotate, so that six clamp pins 11A and 11B are in the open position.

When only the open/close rings 55A are lifted, three clamp levers 12A resist against the biasing force of the biasing members 56 and rotate, so that three clamp pins 11A are in the open position and three clamp pins 11B stays in the close position. When only the open/close rings 55B is lifted, three clamp levers 12B resist against the biasing force of the biasing members 56 and rotate, so that three clamp pins 11B are in the open position and three clamp pins 11A stay in the close position.

The substrate W can be held if at least three clamp pins 11 are in the close position and is contacting the outer edge We of the substrate W. In the present embodiment, by switching the lifting and lowering of the open/close rings 55A and 55B, three holding states of a state in which the substrate W is held by six clamp pins 11A and 11B, a state in which the substrate W is held by three clamp pins 11A, and a state in which the substrate W is held by three clamp pins 11B can be switched.

The stopper cylinder 57 is provided at a position so that a drive rod of the stopper cylinder 57 is directed upward in the vertical direction and faces the drive rod of the open/close cylinder 51. By adjusting the protrusion amount of the drive rod of the stopper cylinder 57, a position where the drive rod of the open/close cylinder 51 can be adjusted, and the open position of the clamp pin 11 by the lifting and lowering of the open/close ring 55 can be adjusted.

### (Synchronization Mechanism)

The synchronization mechanism 60 is a mechanism to synchronize the rotation of the clamp levers 12. As illustrated in FIGS. 2 and 3, the synchronization mechanism 60 includes a synchronization ring 61 and a conversion mechanism 62. The synchronization ring 61 is a member provided around the axis Ax, is rotatable, and cannot be lifted and lowered. The synchronization ring 61 is a ring coaxial with the rotation shaft 41 assembled along the outer circumference of the rotation shaft 41. Although the synchronization ring 61 rotates together with the rotation shaft 41, the synchronization ring 61 also independently rotates around the rotation shaft 41.

A fixation ring 41a is fixed to the outer circumference of the rotation shaft 41. A part of the outer edge of the fixation ring 41a protrudes outward than the outer edge of the synchronization ring 61 and is provided with a cylindrical roller 41b that rotates around an axis in parallel with the axis Ax. Since there are multiple portions protruding outward from the fixation ring 41a, each of which are provided with a roller 41b, a plurality of the rollers 41b is arranged along the outer edge of the fixation ring 41a. A recess to which the outer edge of the synchronization ring 61 contacts is formed in the outer circumference of the roller 41b, and guides the rotation of the synchronization ring 61 around the rotation shaft 41. Two rollers 41b are arranged on top of each other in the vertical direction to the upper and lower synchronization rings 61 described later. Furthermore, the portion of the fixation ring 41a protruding from the outer edge and the roller 41b are configured so as not to interfere a portion of the synchronization ring 61 protruding from the outer edge, which is described later.

Two synchronization rings 61 are arranged vertically. The upper synchronization ring 61 is a synchronization ring 61A that rotates by the lifting and lowering of the lifting ring 15A, and the lower synchronization ring 61 is a synchronization ring 61B that rotates by the lifting and lowering of the lifting ring 15B. Hereinafter, the synchronization rings 61A and 61B are described as the synchronization ring 61 unless otherwise distinguished.

The conversion mechanism 62 is a mechanism that converts the lifting and lowering of the lifting ring 15 by the lifting mechanism 50 to the rotation of the synchronization ring 61 and maintain posture of the lifting ring 15 in a horizontal state. The conversion mechanism 62 includes a swing lever 621, a lifting guide 622, and a rotation guide 623. The swing lever 621 is an L-shaped member that is provided to swing around a fixed shaft 621a fixed to the outer circumference of the rotation shaft 41 as a fulcrum. A vertically-moving shaft 621b is provided to a lower end of the swing lever 621, and a horizontally-moving shaft 621c is provided to an upper end of the swing lever 621.

The lifting guide 622 is fixed to each of the lifting rings 15A and 15B. Furthermore, the lifting guide 622 is arranged at a position corresponding to each clamp base 16, that is, a position corresponding to each clamp lever 12 and clamp pin 11. A horizontally long guide hole 622a is formed in the lifting guide 622. The vertically-moving shaft 621b is rotatably and slidably inserted in the guide hole 622a. The rotation guide 623 is fixed to the synchronization ring 61 so that the rotation guide 623 can rotate around a vertical axis and cannot move vertically. In detail, there are protrusions 61a at multiple locations in the synchronization ring 61, and a shaft 62a extending vertically from the rotation guide 623 is fit in a through hole provided to the protrusion 61a. The protrusion 61a is provided to each of two synchronization rings 61 and is arranged so as to not interfere with each other along the rotation of the synchronization ring 61. A vertically long guide recess 623a is formed in the rotation guide 623. The horizontally-moving shaft 621c is rotatably and slidably inserted in the guide recess 623a.

As the lifting ring 15 is lifted or lowered, the lifting guide 622 biases the vertically-moving shaft 621b via the guide hole 622a to be lifted or lowered, causing the swing lever 621 to swing. By this, the horizontally-moving shaft 621c of the swing lever 621 biases the rotation guide 623 via the guide recess 623a to move horizontally, causing the synchronization ring 61 to rotate.

At least a set of a pair of the conversion mechanisms 62 provided at opposite positions across the axis Ax. In the present embodiment, the conversion mechanism 62 includes a pair of conversion mechanisms 62A connecting the lifting ring 15A and the synchronization ring 61A, a pair of conversion mechanisms 62B connecting the lifting ring 15B and the synchronization ring 61B. That is, the present embodiment has two sets of a pair of the conversion mechanisms 62. It is preferable that the pair of the conversion mechanisms 62A and the pair of the conversion mechanisms 62B are each arranged on the straight line that extends across the axis Ax. Hereinafter, the conversion mechanisms 62A and 62B are described as the conversion mechanism 62 unless otherwise distinguished. Note that, since the set only regulates one direction in the horizontal plane, it is preferable to provide two sets or more for the regulation in two or more direction in the horizontal plane to match the center of the lifting ring 15 and the axis Ax. Accordingly, the matching of the center of the lifting ring 15 and the axis Ax leads to the matching of the center of the substrate W and the axis Ax.

Note that, as described later, the pair of the conversion mechanisms 62 may be slightly displaced from the position on the straight line that extends across the axis Ax if the abnormality of the clamp pin 11 can be detected by the tilting of the lifting ring 15. For example, the pair of the conversion mechanisms 62 may be slightly displaced from the position on the straight line through the axis Ax to avoid the interference between other members such as the clamp base 16. Even in this case, they are included in the opposite positions across the rotation shaft 41. Furthermore, although it is preferable that the straight line on which the pair of the conversion mechanisms 62A is arranged and the straight line on which the pair of the conversion mechanisms 62B is arranged are orthogonal to each other, the straight lines may not be orthogonal to each other to avoid interference with other members.

### (Supplier)

As illustrated in FIG. 1, the supplier 70 is held by the clamp pin 11 and supplies processing liquid on the substrate W rotated by the rotator 30. The supplier 70 supplies the processing liquid on the surface of the substrate W, that is, a surface of the substrate W opposite the table 31a held by the holder 10. The supplier 70 includes a processing-liquid supplying mechanism 71, a processing-liquid holder 72, a lift 73, and a heating unit 74.

The processing-liquid supplying mechanism 71 is a mechanism to supply multiple types of the processing liquid. For example, in the present embodiment, aqueous solution containing pure water (H₂O) and phosphoric acid (H₃PO₄) (hereinafter, referred to as phosphoric acid solution) and aqueous solution containing hydrogen fluoride (HF) is supplied as the processing liquid. The processing-liquid supplying mechanism 71 has a processing-liquid tank 71a to store each processing liquid.

From each processing-liquid tank 71a, individual delivery pipes 71b are connected in parallel to the processing-liquid supplying pipe 71c. An end of the processing-liquid supplying pipe 71c faces the substrate W held by the holder 10. By this, the processing liquid from each processing-liquid tank 71a is supplied on the surface of the substrate W via the individual delivery pipe 71b and the processing-liquid supplying pipe 71c. Each individual delivery pipe 71b is provided with a flow adjustment valve 71d and a flow meter 71e.

The processing-liquid holder 72 is a disc with diameter larger than the substrate W and is a tray in which a wall standing up opposite the rotator 30 is formed on a periphery thereof. An outer bottom surface if the processing-liquid holder 72 faces the substrate W. A discharge port 72a exposed at the substrate-W side is formed by inserting the end of the processing-liquid supplying pipe 71c to the processing-liquid holder 72.

The lift 73 is a mechanism to move the processing-liquid holder 72 in the direction contacting or getting apart from the substrate W. For example, the lift 73 may be various mechanisms to move the processing-liquid holder 72 in the direction in parallel with the shaft of the rotator, such as a cylinder or a ball screw mechanism, however, the details are omitted.

The heating unit 74 heats the processing liquid supplied on the surface of the substrate W by the supplier 70. The heating unit 74 includes a heater 741 provided on a surface of the processing-liquid holder 72 opposite the surface facing the substrate W. The heater 741 is a disc-shaped sheet. A through hole 741a inserted to the processing-liquid supplying pipe 71c is formed in the heater 741.

### (Detector)

As illustrated in FIGS. 5 to 7, the detector 80 detects a height position of the lifting ring 15. The detector 80 is a reflective optical sensor that detects the distance to a detection target without contact. The detector 80 is fixed to the base portion B below the height detection plate 151 and detects the distance to the height detection plate 151. The detector 80 includes a detectors 80A and 80B. The detector 80A is arranged below the height detection plate 151A and detects the height position of the lifting ring 15A using the distance to the height detection plate 151A. The detector 80B is arranged below the height detection plate 151B and detects the height position of the lifting ring 15B using the distance to the height detection plate 151B. Hereinafter, the detectors 80A and 80B, and the height detection plates 151A and 151B are described as the detector 80 and the height detection plate 151 unless otherwise distinguished.

There may be single or multiple detector 80. In the case of single detector 80, the lifting ring 15 is rotated together with the rotator 30 to detect the height positions at multiple locations. In the case of multiple detectors 80, each detector 80 detects the height positions at multiple locations in the circumferential direction.

### (Controller)

The controller 90 controls each portion of the substrate processing apparatus 1. The controller 90 includes a processor that executes programs, a memory that stores various information such as programs and operation conditions, and a driving circuit that drives each component, to achieve various function of the substrate processing apparatus 1. That is, the controller 90 controls the rotation mechanism 40, the lifting mechanism 50, and supplier 70, etc. Furthermore, the controller 90 includes an input device to input information and a display device to display information.

In the present embodiment, the controller 90 includes an open/close controller 91, a rotation controller 92, and a determination unit 93. The open/close controller 91 lifts and lowers the open/close ring 55, lifts and lowers the lifting ring 15 by repulsive force of the magnets 15a and 55a to open and close the clamp pin 11 by controlling the open/close cylinder 51 of the lifting mechanism 50. When the open/close ring 55 is lifted so that the lifting ring 15 is lifted, the clamp lever 12 resists against the biasing force of the biasing member 56 and rotates, so that the clamp pin 11 is in the open state apart from the outer edge We of the substrate W. When the open/close ring 55 is lowered so that the lifting ring 15 is lowered, the clamp lever 12 rotates by the biasing force by the biasing member 56, so that the clamp pin 11 is in the close state contacting the outer edge We of the substrate W.

The rotation controller 92 controls the rotation of the substrate held by the rotator 30 and the clamp pin 11 by controlling the drive source 42 of the rotation mechanism 40. Furthermore, the rotation controller 92 can rotate the lifting ring 15 together with the rotator 30 to change the location in the lifting ring 15 detected by the detector 80.

The determination unit 93 determines whether the holding of the substrate W by the clamp pin 11 is normal or not based on the height position of the lifting ring 15 detected by the detector 80. As illustrated in FIG. 5, the holding of the substrate W by the clamp pin is determined normal if the difference between the height position Da of the lifting ring 15 at each location detected by the detector 80 is within the predetermined threshold. FIG. 5a indicates that the holding by the clamp pin 11A is normal, and FIG. 5a indicates that the holding by the clamp pin 11B is normal.

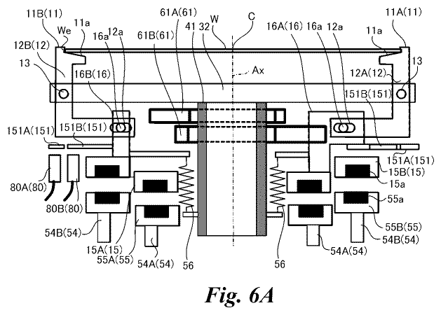

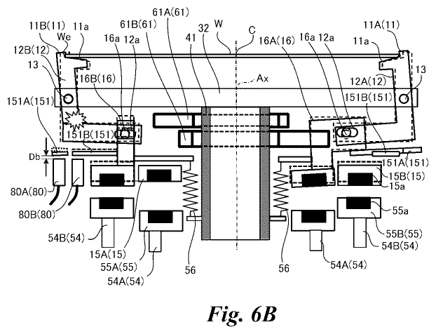

FIG. 6a shows when the holding by the clamp pin 11 is normal and the height position of the lifting ring is normal. FIG. 6b shows when the holding by the clamp pin 11 is abnormal and the height position of the lifting ring is abnormal. As illustrated in FIG. 6b, it can be determined that the holding of the substrate W by the clamp pin 11 is abnormal and the lifting ring 15 is tilted if the difference between the height position Db of the lifting ring 15 at each location detected by the detector 80 is not within the predetermined threshold. FIG. 6b shows when the holding by the clamp pin 11B is abnormal, and in this case, the tilting of the lifting ring 15A of the clamp pin 11A with normal holding increases and the height detection plate 151A is lowered. Meanwhile, the lifting ring 15B of the clamp pin 11B with abnormal holding is lowered from the normal height (refer FIG. 6a). Accordingly, the detectors 80A and 80B can detect the abnormality when the difference of the height position Db exceeds the predetermined threshold, and can detect which of the clamp pins 11A or 11B is abnormal depending on which of the difference of the height position Db detected by the detectors 80A and 80B is larger.

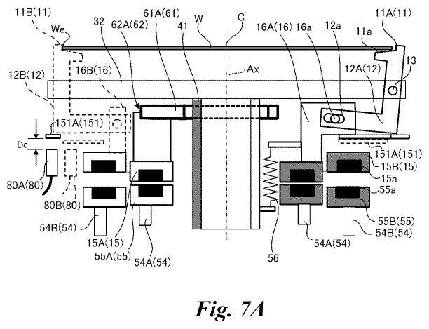

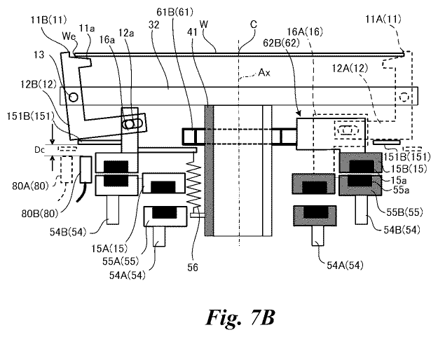

Note that, as illustrated in FIG. 7, the determination unit 93 can determine that the clamp pin 11 is in the open position apart from the substrate W if the difference between the height position Dc of the lifting ring 15 at each location detected by the detector 80 is within the predetermined threshold. FIG. 7a indicates that the clamp pin 11A is in the open position while only the clamp pin 11B is holding, and FIG. 7b indicates that the clamp pin 11B is in the open position while only the clamp pin 11A is holding.

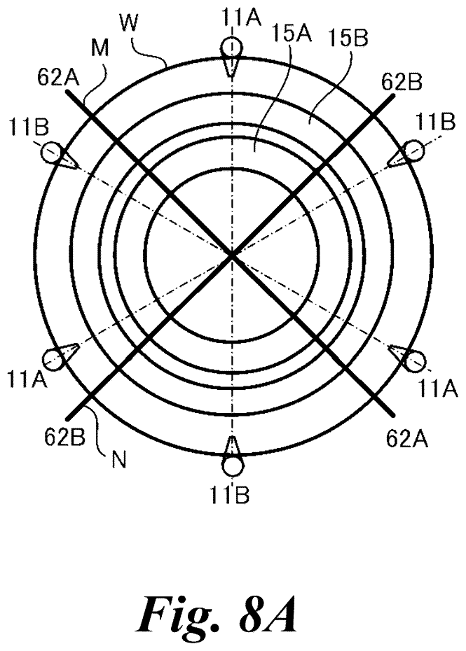

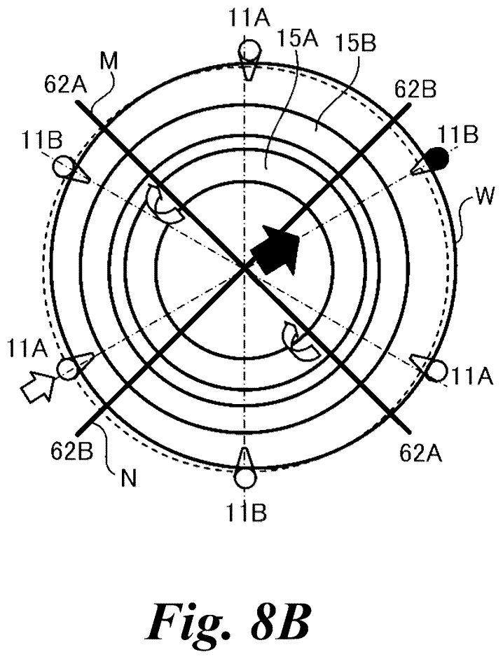

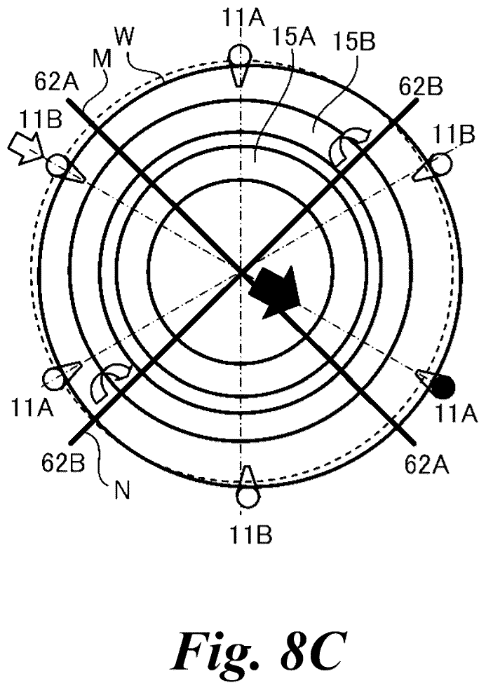

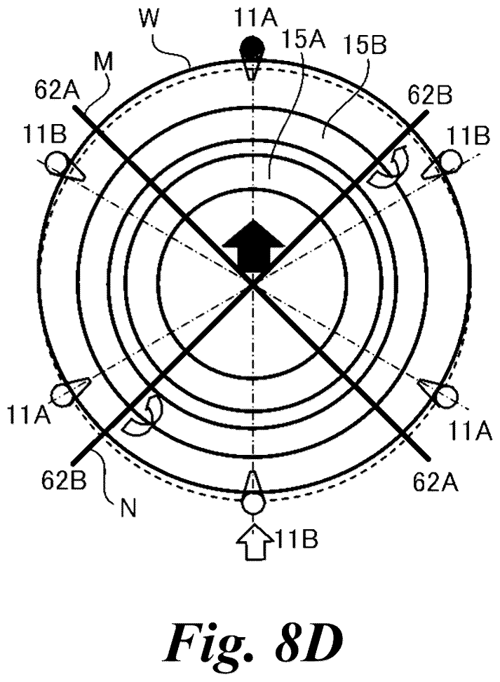

The principle and scheme of such determination is described referring to FIG. 8. In the following description, a mechanism that opens and closes the clamp pin 11A is called an A-side mechanism, and a mechanism that opens and closes the clamp pin 11B is called a B-side mechanism. Furthermore, a line connecting the locations where the pair of the conversion mechanisms 62A is arranged is called M, and a line connecting the locations where the pair of the conversion mechanisms 62B is arranged is called N.

FIG. 8a indicates a state in which the holding of the substrate W by all clamp pins 11A and 11B is normal. In such a normal state, the center C of the substrate W matches with the axis Ax of the rotation, and the substrate W and the lifting rings 15A and 15B are maintained horizontal.

FIG. 8b indicates a state in which the holding by either of the clamp pins 11B at the B-side is abnormal. In this state, the abnormal clamp pin 11B (indicated by black) and the substrate W is pressed in the direction indicated by the white arrow by the biasing force from the opposite clamp pin 11A. Accordingly, as indicated by the arc-shaped arrow, the corresponding lifting ring 15B tilts to a position lower than the normal position with M as the axis, and the center C of the substrate W is displaced from the axis Ax of the rotation in the direction of the black arrow in the figure. Since the normal clamp pin 11A follows the displacement of the substrate W and is also displaced from the normal position, the lifting ring 15A also tilts to a position lower than the normal position.

Accordingly, locations where the distance to the lifting rings 15A and 15B detected by the detectors 80A and 80B is smaller than the predetermined threshold occur, and the abnormality is determined. Then, since the tilting of the lifting ring 15B corresponding to the abnormal clamp pin 11B increases and the difference of the distance to the lifting ring 15B at multiple locations detected by the detector 80B becomes larger than the predetermined threshold, it is determined that the holding of either of the clamp pin 11B is abnormal.

FIG. 8c indicates a state in which the holding by either of the clamp pins 11A at A-side is abnormal, and FIG. 8d shows a state in which the holding by the clamp pin 11A at A-side other than that of FIG. 8c is abnormal. Also, in these cases, the distance to the lifting rings 15A and 15B detected by the detectors 80A and 80B is smaller than the predetermined threshold, and the abnormality is determined. Then, since the tilting of the lifting ring 15A corresponding to the abnormal clamp pin 11A with N as the axis increases, it is determined that the holding of either of the clamp pin 11A is abnormal.

### [Action]

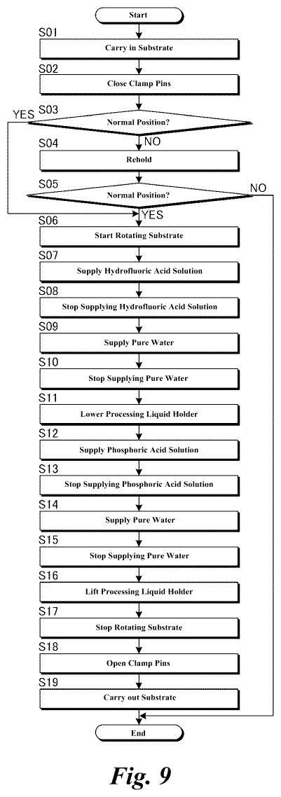

The action of the substrate processing apparatus 1 of the above present embodiment is described referring to the flowchart of FIG. 9, in addition to the above FIGS. 1 to 8. Note that the substrate processing method to process the substrate by the below procedures is also aspects of the present embodiment.

Firstly, as shown in FIG. 2, the lifting ring 15 is lifted by the open/close cylinder 51 to rotate the clamp lever 12 against the biasing force of the biasing member 56, so that the clamp pin 11 is in the open position. Furthermore, the processing-liquid holder 72 of the supplier 70 illustrated in FIG. 1 is in the standby position above.

In this state, the substrate W loaded on a robot hand of a transportation robot is carried in between the processing-liquid holder 72 and the rotator 30 (Step S01). The open/close cylinder 51 is operated to lower the lifting ring 15, so that the clamp lever 12 is rotated by the biasing force of the biasing member 56 to move the plurality of the clamp pins 11 to the close position (Step S02).

Then, the tilted surface of the support 11a moving together with the clamp pin 11 moves and slides while supporting the lower edge of the outer edge We of the substrate W, and finally the clamp pin 11 contacts and holds the outer edge We of the substrate W.

At this time, the open/close cylinders 51A and 51B lowers the lifting rings 15A and 15B, so that all of the six clamp pins 11A and 11B holds the outer edge We of the substrate W. By this, the center C of the substrate W is positioned at the axis Ax of rotation by six clamp pins 11A and 11B.

As described above, if the determination unit 93 determines that the height positions the lifting ring 15 at multiple locations detected by the detector 80 is normal (Step S03: YES) (the state in FIG. 5), the drive source 42 operates to start rotating the rotator 30 (Step S06). The rotator 30 rotates at the predefined speed that is relatively slow (for example, about 50 rpm), and the substrate W rotates at said predefined speed together with the holder 10.

If the determination unit 93 determines that either of the clamp pin 11A or 11B is not in the normal position (Step S03: NO), the reholding action of the substrate W is performed (Step S04). That is, by lifting the lifting ring 15, the clamp pin 11 moves slightly apart from the outer edge We of the substrate W while maintaining the support of the substrate W by the support 11a. Then, the lifting ring is lowered again, and the clamp pin 11 holds the outer edge We of the substrate W.

After the reholding action, if the determination unit 93 determines that the clamp pin 11 is at the normal position (Step S05: YES), the drive source 42 operates to start rotating the rotator 30 (Step S06). After the reholding action, if the determination unit 93 determines that the holding by the clamp pin 11 is not normal (Step S05: NO), the plurality of the clamp pins 11 are moved to the open position (Step S18). Then, the robot hand carries out the substrate W (Step S19).

When the holding by the clamp pin 11 becomes normal and the rotator 30 starts to rotate, etching liquid that is the processing liquid is supplied from the discharge port 72a of the processing-liquid holder 72 to a space between the processing-liquid holder 72 and the surface of the substrate W by the processing-liquid supplying mechanism 71. That is, when hydrofluoric acid solution is supplied on the surface of the rotating substrate W, the etching liquid sequentially moves toward the outer edge We of the substrate W, so that the surface of the substrate W is etched, and oxide film and organic substances are removed.

Next, the processing-liquid supplying mechanism 71 stops supplying the etching liquid (Step S08), and supplies pure water from the discharge port 72a to the space between the processing-liquid holder 72 and the surface of the substrate W (Step S09). When the pure water is supplied on the surface of the rotating substrate W, the pure water sequentially moves toward the outer edge We of the substrate W, so that the hydrofluoric acid solution is washed away from the surface of the substrate W. Then, the processing-liquid supplying mechanism 71 stops supplying the pure water (Step S10).

The processing-liquid holder 72 lowers and moves the heater 741 closer to the substrate W (Step S11). The processing-liquid supplying mechanism 71 supplies phosphoric acid solution to the space between the processing-liquid holder 72 and the surface of the substrate W (Step S12). Accordingly, the phosphoric acid solution supplied between the processing-liquid holder 72 and the surface of the substrate W is heated by the processing-liquid holder heated by the heater 741 to high temperature.

In this state, the phosphoric acid solution is continuously supplied from the discharge port 72a of the processing-liquid holder 72 to the surface of the substrate W, and sequentially moves toward the outer edge We of the substrate W, so that the pure water on the surface of the substrate W is replaced with the phosphoric acid solution, and nitride film is removed by etching.

Next, the processing-liquid supplying mechanism 71 stops supplying the phosphoric acid solution, and the processing-liquid holder 72 is lifted (Step S13). The processing-liquid supplying mechanism 71 supplies pure water from the discharge port 72a to the space between the processing-liquid holder 72 and the surface of the substrate W (Step S14). When the pure water is supplied on the surface of the rotating substrate W, the pure water sequentially moves toward the outer edge We of the substrate W, so that the phosphoric acid solution is washed away from the surface of the substrate W.

Then, when the predetermined washing time elapses, the processing-liquid supplying mechanism 71 stops supplying the pure water (Step S15). Then, the processing-liquid holder 72 is lifted (Step S16), and the drive source 42 is stopped so that the rotator 30 stops rotating and the substrate W stops rotating (Step S17).

Then, the robot hand is inserted below the substrate W, and the open/close cylinder 51 is operated to lift the lifting ring 15, so that the clamp lever 12 is rotated to move the plurality of the clamp pins 11 to the open position (Step S18). Then, the robot hand carries out the substrate W (Step S19).

Note that the holding by the clamp pins 11A and 11B are changed to reduce uneven processing. That is, a state in which six clamp pins 11A and 11B are holding the substrate W, a state in which three clamp pins 11B are in the open position while only three clamp pins 11A are holding the substrate W, and a state in which three clamp pins 11A are in the open position while only three clamp pins 11B are holding the substrate W are switched. This prevents specific clamp pins 11A and 11B from contacting the substrate W for a long time, and the uneven processing due to the processing liquid retaining at the contact position can be suppressed.

However, when switching the state in which only three clamp pins 11A are holding and the state in which only three clamp pins 11B are holding, to prevent the displacement of the center of the substrate W and the holding error, the switching is performed via the state in which six clamp pins 11A and 11B are holding. That is, for example, the changing action may be performed as follows: hold by six clamp pins (11A, 11B)→hold by three clamp pins (11A)→hold by six clamp pins (11A, 11B)→hold by three clamp pins (11B)→hold by six clamp pins (11A, 11B)→hold by three clamp pins (11A)→hold by six clamp pins (11A, 11B)→hold by three clamp pins (11B)→hold by six clamp pins (11A, 11B), and so on. Then, six clamp pins 11A and 11B are always in a holding state before starting and stopping the rotation.

Furthermore, also during the processing of the substrate W (Steps S06 to S17), if the determination unit 93 determines that the holding by the clamp pin 11 is abnormal based on the height position of the lifting ring 15 detected by the detector 80, the controller 90 stops processing the substrate. That is, if the variation of the height position of the lifting ring 15 during the rotation exceeds the predetermined threshold range, the controller 90 determines that the holding by the clamp pin 11 is abnormal and immediately takes actions such as stopping the apparatus.

### [Effect]

(1) The substrate processing apparatus 1 of the present embodiment includes: at least three clamp pins 11 holding the outer edge We of the substrate W; the clamp lever 12, to which the clamp pins 11 are provided and which moves the clamp pins 11 between the open position that is apart from the outer edge We of the substrate W and the close position where the clamp pins 11 contact the outer edge We of the substrate W and hold the substrate W according to rotation around the axis (the rotation shaft 13) in the horizontal direction; the lifting ring 15 rotating the clamp lever 12 according to lifting and lowering; the rotator 30 to which the rotation shaft 13 is provided and rotating the substrate W held by the clamp pins 11, together with the clamp lever 12, and the lifting ring 15; the lifting mechanism 50 lifting and lowering the lifting ring 15; the rotation mechanism rotating the rotator 30 around the axis Ax (the vertical rotation shaft 41); the biasing member 56 biasing the clamp lever 12 in a direction the clamp pins 11 moves to the close position; the synchronization ring 61 that is rotatable around the axis Ax and that cannot be lifted and lowered; the conversion mechanism 62 converting lifting and lowering of the lifting ring 15 by the lifting mechanism 50 to the rotation of the synchronization ring 61 while maintaining the posture of the lifting ring 15 in the horizontal direction; and a supplier 70 and supplying processing liquid on the substrate W held by the clamp pin 11 and rotated by the rotator 30.

Therefore, the lifting ring 15 is lifted by the lifting mechanism 50 to rotate the clamp lever 12 against the biasing force of the biasing member 56, so that the clamp pin 11 is in the open position. The lifting ring 15 is lowered by the lifting mechanism 50 to rotate the clamp lever 12 according to the biasing force of the biasing member 56, so that the clamp pin 11 is in the close position. At this time, since the lifting ring 15 is connected to the synchronization ring 61 that is rotatable and cannot be lifted and lowered via the conversion mechanism 62, the lifting ring 15 is lowered while being maintained in the horizontal direction. Therefore, there is no variation in the operation of each clamp pin 11 due to the tilting of the lifting ring 15, and the clamp pins 11 synchronously contact the outer edge We of the substrate W. Since the biasing force of the biasing member 56 acts on at least three of the clamp pins 11 to hold the outer edge We of the substrate W, the substrate W is positioned in a state in which net force by all of the clamp pins 11 is zero, that is, in a state in which the center C of the substrate W is positioned to match with the axis Ax.

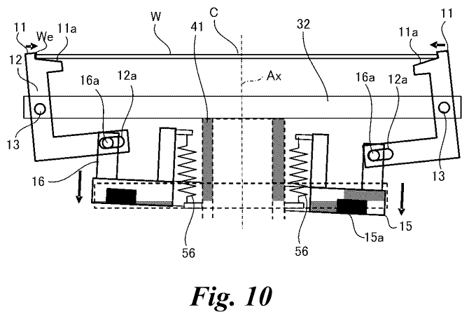

For example, as illustrated in FIG. 10, even in the configuration in which the lifting ring 15 vertically moves to open and close the clamp pin 11 and there is no synchronization mechanism 60 (the synchronization ring 61), the net force of the clamp pins 11 become zero, and the apparatus can hold the substrate W. However, if there is no synchronization mechanism 60, when the substrate W is held with the force of all clamp pins 11 is equivalent due to the net force of the biasing member 56, the centrifugal force generated by the rotation of the substrate W moves the substrate W in the centrifugal direction, displacing the center C of the substrate W from the axis Ax (the rotation shaft 41). Furthermore, when the clamp pin 11 and the clamp lever 12 are not normal, the center C of the substrate W is displaced from the axis Ax. The state in which the force of all clamp pins 11 to hold the substrate W is equivalent due to the net force of the biasing member 56 means the state is balanced and there is no biasing force of the biasing member 56. If the biasing force of the biasing member 56 is not present, there is a problem that the lifting ring 15 may tilt, as illustrated in FIG. 10, This is because the lifting ring 15 is restricted in the rotational direction, but is not restricted in the vertical direction. In the present embodiment, since the conversion mechanism 62 and the synchronization mechanism 60 restricts the lifting ring 15 is in the vertical direction without restricting the rotation, the lifting ring 15 can be maintained horizontal, and the center C of the substrate W and the axis Ax can be matched.

That is, in the present embodiment, the lifting ring 15 is connected to the synchronization ring 61 via the conversion mechanism 62, and the synchronization ring 61 rotates according to the lifting and lowering of the lifting ring 15 without being lifted or lowered. Therefore, when rotating the substrate W, even if force to rotate the clamp lever 12 is applied due to the centrifugal force applied to either of the clamp pins 11, the movement of the lifting ring 15 supporting the clamp lever 12 to rise is suppressed by the synchronization ring 61. Even if force to rotate one clamp pin 11 and the clamp lever 12 and lift the lifting ring 15 is applied due to the centrifugal force, since the other clamp pins 11 are synchronized, force to open the other clamp pins 11 and the clamp lever 12 is required for actually lifting the lifting ring 15. Therefore, force to lift the lifting ring 15 and rotate the synchronization ring 61 becomes resistance, abd tge clamp pin 11 and the clamp lever 12 cannot be opened even when the substrate W pushes the clamp pin 11 and the clamp lever 12 by the centrifugal force. By this, since it becomes difficult for the clamp lever 12 to rotate and the movement of the clamp pin 11 to the open position can be suppressed, the positioning of the substrate W is stabilized.

Furthermore, to lower the lifting ring 15, the clamp lever 12 closes, and the clamp pin 11 contacting the outer edge We of the substrate W moves the substrate W to move the center of the substrate W to the center of rotation (axis Ax). At this time, not all clamp pins 11 contact the outer edge We of the substrate W at the same time. When the substrate W is loaded on the robot, the substrate W is placed in a biased state due to the tilted surface of the clamp pin 11. That is, when lifting ring 15 is lowered and the clamp pin1 11 is moved in the closing direction, a part of the clamp pin 11 first contacts the outer edge We of the substrate W. For example, if there is no synchronization mechanism 60, when said movement stops in the middle, only the clamp pin 11 not contacting the outer edge We is moved, so that the substrate W is held in a state the lifting ring 15 is tilted. In the present embodiment, since the conversion mechanism 62 and the synchronization mechanism 60 lifts and lower the lifting ring 15 while maintaining the lifting ring 15 horizontal, even when the timings of the clamp pin 11 contacting the outer edge We of the carried substrate W vary, the tilting of the lifting ring 15 is suppressed, and the center of the substrate W and the axis Ax can be matched when the clamp pin 11 is finally closed.

Furthermore, for example, an axial slider (linear guide) in parallel with the axis Ax of the rotator 30 may be installed in the lifting ring 15 to lift and lower the lifting ring 15. However, in this case, the weight of the rotator 30 and the rotation shaft 41 increases by installing the axial slider, increasing load on the motor. Furthermore, in order to lift and lower the lifting ring 15 without eccentric rotation while maintaining the horizontal state, a plurality of the axial sliders need to be arranged opposite each other across the rotation shaft 41, further increasing the weight. In the present embodiment, since the synchronization ring 61 rotating coaxially with the rotation shaft 41 via the conversion mechanism 62 is utilized, the weight of the rotating portion can be reduced, and the eccentric rotation can be suppressed.

Furthermore, for example, a cylindrical slide elongated in the axial direction may be moved along the axis to lift and lower the lifting ring 15 to suppress the lifting ring 15 to tilt. However, to smoothly lift and lower the axis relative to the cylindrical slide, the diameter of the hole of the cylinder needs to be sufficiently larger than the diameter of the axis. That is, since a gap (play) is formed between the hole of the cylinder and the axis, the axis easily tilts. By this, the lifting ring 15 also tilts and the clamp lever 12 tilts, so that the center of the substrate W cannot be positioned at the axis Ax. Furthermore, if the diameter of the hole of the cylinder is set so that the play is not formed between the axis, the axis and the cylinder contacts more, which produces resistance, and the lifting ring 15 may not be smoothly lifted and lowered. In the present embodiment, since the conversion mechanism 62 converts the lifting and lowering of the lifting ring 15 to the rotation of the synchronization ring 61, posture of the lifting ring 15 maintained in the horizontal state, preventing such rattling.

(2) The substrate processing apparatus 1 includes the detector 80 detecting the height position of the lifting ring 15, and the determination unit 93 determining whether the holding of the substrate W by the clamp pin 11 is normal or not based on the height position of the lifting ring 15 detected by the detector 80.

If the clamp pin 11 and the clamp lever 12 are abnormal and the clamp pin 11 cannot hold the substrate W, the lifting ring 15 is tilted with a line connecting the pair of the conversion mechanism 62 as the axis. Therefore, the determination unit 93 can determine the holding of the substrate W by the clamp pin 11 abnormal based on the height position of the lifting ring 15, and the holding error of the substrate W and the failure of the apparatus can be prevented.

(3) The lifting mechanism 50 lifts and lowers the lifting ring 15 without contact by repulsive force of the magnets 15a and 55a. Therefore, the lifting ring 15 can be lifted and lowered while rotating together with the rotator 30. Furthermore, since the space is produced between the lifting mechanism 50 and the lifting ring 15, the determination unit 93 can determine the holding of the substrate W abnormal by the change in the height position of the lifting ring 15.

(4) Six or more clamp pins 11 are provided, in which three or more clamp pins 11 arranged one each around the rotation shaft 41 form a set, and at least a set of the clamp pins 11 is provided to the lifting mechanism 50, the lifting ring 15, the synchronization ring 61, and the conversion mechanism 62. Therefore, three clamp pins 11 holding the substrate W can be changed during the processing, and the uneven processing due to the retaining of the processing liquid can be prevented.

Furthermore, three is the least number of the clamp pins 11 that can hold the substrate W and when the load to either one of the clamp pins 11 becomes larger due to the centrifugal force, the substrate W cannot be held by the other two clamp pins 11, increasing the displacement. However, as described above, in the holding of the substrate W by the clamp pin of the present embodiment, by using the synchronization ring 61 and the conversion mechanism 62, it is difficult for three clamp pins 11 to be displaced even when the centrifugal force is applied, and thus the holding of the substrate W can be stably changed.

Furthermore, as described above, if the holding by one set of the clamp pins 11 is abnormal, the tilting of the lifting ring 15 with the other set that is abnormal increases, and since the difference is produced between the sets, it can be determined which clamp pin 11 in which set is abnormal.

(5) The conversion mechanism 62 includes the swing lever that swings as the horizontal fixed shaft orthogonal to the axis Ax and converts the lifting and lowering of the lifting ring 15 to the rotation of the synchronization ring 61. Therefore, the swing lever 621 swinging around the fixed shaft as a fulcrum can efficiently convert the lifting and lowering action of the lifting ring 15 to the horizontal action and rotate the synchronization ring 61. Note that, by providing a plurality of the conversion mechanisms 62 around the rotation shaft 41, the lifting ring 15 can be lifted and lowered while more stably maintaining the horizontal state, stabilizing the position of the clamp pin 11.

### Modified Example

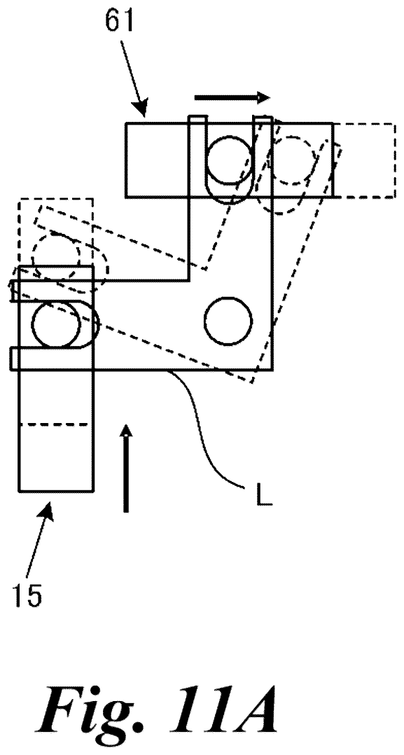

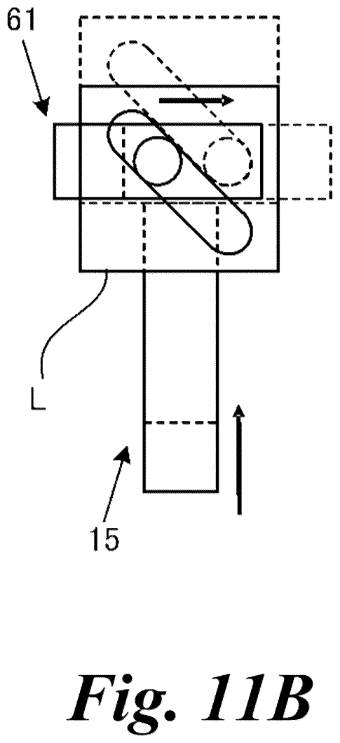

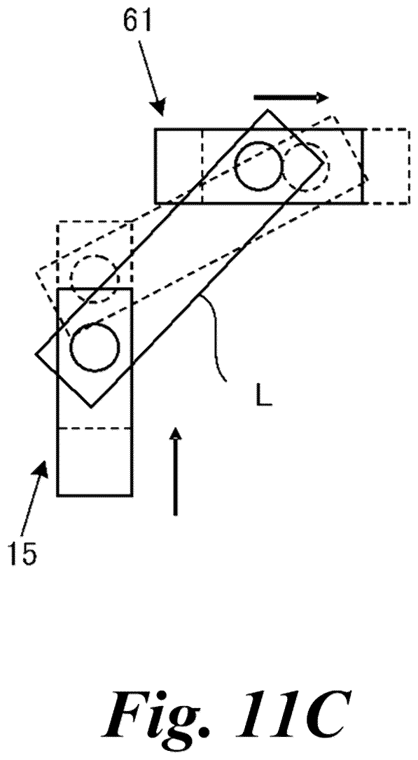

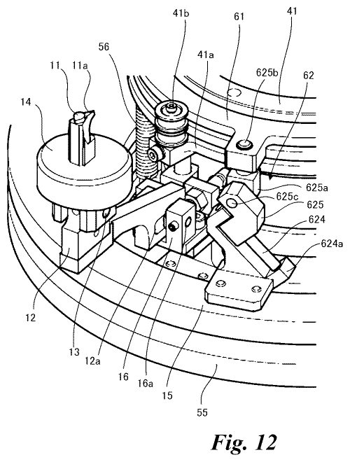

(1) The conversion mechanism may convert the lifting and lowering action of the lifting ring 15 to the rotation of the synchronization ring 61. In the above embodiment, as illustrated in FIG. 11a, the lifting and lowering action is converted to rotation using the L-shaped link L in principle, however, for example, as illustrated in FIG. 12, the conversion mechanism 62 may be formed by a slide shaft 624 provided to the lifting ring 15 and tilted relative to the axis Ax, and a slider 625 that is connected to the synchronization ring 61 and moves along the slide shaft 624 which is lifted and lowered together with the lifting ring 15 to rotate the synchronization ring 61.

In detail, the slide shaft 624 is a cylindrical member and is provided to a slide shaft base 624a fixed to the lifting ring 15. The slider 625 includes a sleeve into which the slide shaft 624 is inserted. In the synchronization ring 61, a conversion member 625a is horizontally rotatably provided to a swing shaft 625b in parallel with the rotation shaft 41. The slider 625 is radially slidably connected to the conversion member 625a via a radial shaft 625c in the radial direction of the rotation of the rotation shaft 41.

When the lifting ring 15 is lifted, the slide shaft 624 is lifted, and the slider 625 moves along the tilting of the slide shaft 624 and biases the radial shaft 625c in the tangential direction of the rotation of the synchronization ring 61. Accordingly, since the conversion member 625a is biased together with the radial shaft 625c, the conversion member 625a rotates around the swing shaft 625b and the synchronization ring 61 is biased in the circumferential direction and rotates.

Accordingly, the deviation in the radial direction produced between the linear action of the slider 625 and the rotational action of the synchronization ring 61 can be absorbed by the sliding action of the slider 625 relative to the radial shaft 625c and the rotation of the conversion member 625a. That is, the operation of the conversion mechanism 62 can be stabilized by providing degrees of freedom in two directions.

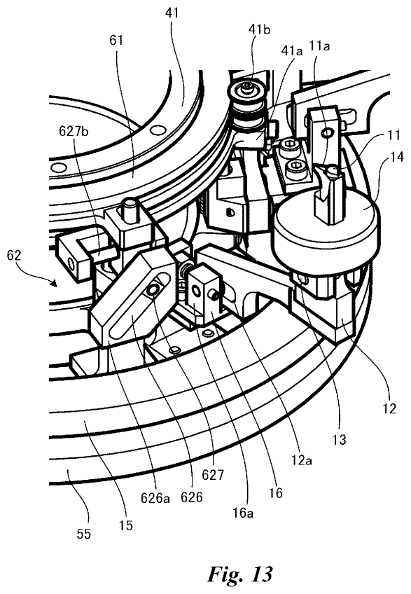

Furthermore, as illustrated in FIG. 11b, the lifting and lowering action may be changed to rotation by the link L using a cam. That is, as illustrated in FIG. 13, the conversion mechanism 62 may be formed by a cam 626 provided to the lifting ring 15 and tilted relative to the axis Ax, and a cam shaft 627 that is connected to the synchronization ring 61 and moves along the cam 626 which is lifted and lowered together with the lifting ring 15 to rotate the synchronization ring 61.

In detail, the cam 626 is a long hole formed in a cam base 626a fixed to the lifting ring 15. The cam 626 is tilted relative to the axis Ax. A cam shaft 627 is a cylindrical member into which the cam 626 is inserted. In the synchronization ring 61, the cam shaft 627 is horizontally rotatably provided around the axis in parallel with the axis Ax. A horizontal shaft 627b fixed in the tangential direction of the rotation of the synchronization ring 61 is slidably inserted to the rotation shaft 41.

When the lifting ring 15 is lifted, the cam 626 is lifted, and the cam shaft 627 moves along the tilting in the cam 626 and biases the synchronization ring 61 in the tangential direction of the rotation while moving in the horizontal direction along the horizontal shaft 627b. Accordingly, the synchronization ring 61 is biased in the circumferential direction and rotates.

According to the conversion mechanism 62 with such a cam 626, since larger power is required for the clamp pin 11 to be in the open position due to the friction force between the cam 626 and the cam shaft 627, it becomes difficult for the clamp pin 11 to be displaced even when the centrifugal force is applied.

Note that, as illustrated in FIG. 11c, the conversion mechanism 62 may convert the lifting and lowering action to the rotational action by a linear link L with two rotation fulcrums.

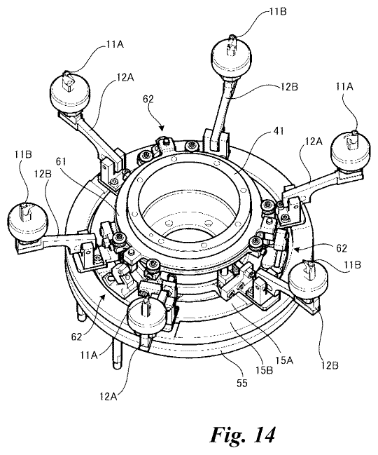

(2) If the clamp pins holding the substrate W are not changed, single synchronization ring 61 may be used. For example, as illustrated in FIG. 14, three conversion mechanisms 62 may be fixed inside the lifting ring 15A and connected to synchronization ring 61 to lift and lower the lifting ring 15A while maintaining the lifting ring 15A horizontal. Three clamp pins 11A are arranged to the lifting ring 15A. Three clamp pins 11B are arranged to the lifting ring 15B, and the conversion mechanism 62 is not provided. The open/close ring 55 and the lifting rings 15A and 15B are common and the lifting rings 15A and 15B are lifted and lowered by lifting or lowering the open/close ring 55. By this, the center C of the substrate W is positioned at the axis Ax of rotation by six clamp pins 11A and 11B. In detail, the center C of the substrate W is positioned (centered) at the axis Ax by three clamp pins 11A provided to the lifting ring 15A, and the outer circumference of the centered substrate W is held by three clamp pins 11B. At this time, the substrate W is moved from the direction where the conversion mechanism 62 is arranged to the direction where the center C of the substrate W is at the axis Ax by the lifting and lowering action of the two lifting rings and the rotational action of the synchronization ring 61 to center the substrate W. When the holding of the substrate W is normal, it is confirmed that the lifting rings 15A and 15B are both horizontal and at the same height, and the substrate W is normally centered and held. When either of the clamp pins 11A and 11B are abnormal, the abnormality can be determined by the lowering and tilting of the lifting rings 15A and 15B. A number of the clamp pins 11 is not limited and at least three is preferable. Therefore, the modified example of FIG. 14 may be an aspect that does not include the lifting ring 15B and three clamp pins 11B.

(3) The lifting mechanism 50 is not limited to the above embodiment. For example, the lifting mechanism 50 may employ a configuration utilizing a contact-type configuration such as a configuration in which a cam follower that can be lifted and lowered is used to contact a rotating roller of the cam follower to the lifting ring 15 and lifting and lowering said roller, while allowing the rotation of the lifting ring 15, instead of the non-contact-type configuration by the repulsive force of the magnet.

(4) The detail of the processing and the processing liquid of the substrate processing apparatus 1 are not limited to the above-described examples. Also, the substrate W that is the processing target and the film are not limited to the above-described examples.

### Other Embodiment

As above, although the modified examples of the embodiments and portions according to the present disclosure are described, these modified examples of the embodiments and portions are only presented as examples and are not intended to limit the scope of the claims. These new embodiments described above can be implemented in other various forms, and various omission, replacement, modification, and change may be performed without departing from an abstract of the invention. These embodiments and modification thereof are included in the scope and abstract of the invention, and are included in the invention described in the scope of the claims.

### REFERENCE SIGN

1: substrate processing apparatus
10: holder
11, 11A, 11B: clamp pin
11a: support
12, 12A, 12B: clamp lever
12a: connection hole
13: rotation shaft
14: cover
14a: tilted surface
15, 15A, 15B: lifting ring
15a, 55a: magnet
16, 16A, 16B: clamp base
16a: lifting shaft
30: rotator
31: rotation cover
31a: table
31b: side surface
31c: discharge port
31d: through hole
32: rotation base
40: rotation mechanism
41: rotation shaft
41a: fixed ring
41B: roller
42: drive source
50: lifting mechanism
51, 51A, 51B: open/close cylinder
52, 52A, 52B: open/close lever
52a: fulcrum
52b: support member
53, 53A, 53B: open/close lifter
53a: support member
53b: linear guide
54, 54A, 54B: open/close rod
55, 55A, 55B: open/close ring
56: biasing member
57: stopper cylinder
60: synchronization mechanism
61, 61A, 61B: synchronization ring
61a: protrusion
62, 62A, 62B: conversion mechanism
62a: shaft
70: supplier
71: processing-liquid supplying mechanism
71a: processing-liquid tank
71b: individual delivery pipe
71c: processing-liquid supplying pipe
71d: flow adjustment valve
71e: flow meter
72: processing-liquid holder
72a: discharge port
73: lifting unit
74: heating unit
80, 80A, 80B: detector
90: controller
91: open/close controller
92: rotation controller
93: determination unit
123: clamp lever
151, 151A, 151B: height detection plate
621: swing lever
621a: fixed shaft
621b: vertically-moving shaft
621c: horizontally-moving shaft
622: lifting guide
622a: guide hole
623: rotation guide
623a: guide recess
624: slide shaft
624a: slide shaft base
624b: conversion member
625: slider
625a: conversion member
625b: swing shaft
625c: radial shaft
626: cam
626a: cam base
627: cam shaft
627b: horizontal shaft
741: heater
741a: through hole

1.-7. (canceled)

8. A substrate processing apparatus, comprising:
at least three clamp pins holding an outer edge of a substrate;
a clamp lever to which the clamp pins are provided and which moves the clamp pins between an open position that is apart from the outer edge of the substrate and a close position where the clamp pins contact the outer edge of the substrate and hold the substrate according to rotation around a horizontal rotation axis;
a lifting ring rotating the clamp lever according to lifting and lowering;
a rotator to which the horizontal rotation axis of the clamp lever is provided and which rotates the substrate held by the clamp pins together with the clamp lever and the lifting ring;
a rotation mechanism rotating the rotator around a vertical rotation axis;
a lifting mechanism lifting and lowering the lifting ring along the vertical rotation axis;
a biasing member biasing the clamp lever in a direction the clamp pins move to the close position;
a synchronization ring that is rotatable around the vertical rotation axis and that cannot be lifted and lowered;
a conversion mechanism converting lifting and lowering of the lifting ring by the lifting mechanism to rotation of the synchronization ring while maintaining posture of the lifting ring in the horizontal direction; and
a supplier and supplying processing liquid on the substrate held by the clamp pin and rotated by the rotator.

9. The substrate processing apparatus according to claim 8, further comprising:
a detector detecting a height position of the lifting ring; and
a determination unit determining whether holding if the substrate by the clamp pin is normal or not based on the height position of the lifting ring detected by the detector.

10. The substrate processing apparatus according to claim 9, wherein the lifting mechanism lifts or lowers the lifting ring by repulsive force of a magnet without contact.

11. The substrate processing apparatus according to claim 8, wherein:
at least six clamp pins are provided, in which three of the clamp pins arranged one each around the vertical rotation axis from a set, and
at least one set of the clamp pins is provided with the lifting mechanism, the lifting ring, the synchronization ring, and the conversion mechanism are.

12. The substrate processing apparatus according to claim 8, wherein the conversion mechanism includes a swing lever that swings around a fixed shaft in a horizontal direction orthogonal to the vertical rotation axis as a fulcrum, and converts lifting and lowering of the lifting ring to rotation of the synchronization ring.

13. The substrate processing apparatus according to claim 8, wherein the conversion mechanism includes:
a slide shaft provided to the lifting ring and tilted relative to the vertical rotation axis; and
a slider connected to the synchronization ring and moving along the slide shaft which is lifted and lowered together with the lifting ring to rotate the synchronization ring.

14. The substrate processing apparatus according to claim 8, wherein the conversion mechanism includes:
a cam provided to the lifting ring and tilted relative to the vertical rotation axis; and
a cam shaft connected to the synchronization ring and moving along the cam which is lifted and lowered together with the lifting ring to rotate the synchronization ring.
